(19) United States
(12) Patent Application Publication
(10) Pub. No.: US 2007/0252276 A1
(43) Pub. Date: Nov. 1, 2007

(54) Thin film for vertical form fill and seal packaging of flowable materials

(76) Inventor: Ian Lloyd-George, Lachine (CA)

Correspondence Address: OGILVY RENAULT LLP, 1981 MCGILL COLLEGE AVENUE, SUITE 1600, MONTREAL, QC, H3A2Y3, CA

(21) Appl. No.: 11/412,980

(22) Filed: Apr. 28, 2006

(51) Int. Cl. H01L 23/48

(52) U.S. Cl. 257/750

(57) ABSTRACT

A multi-layer film for vertical form, film and seal systems for liquid, powder, granules and/or other flowables packaging, said multi-layer comprising: an inner layer made of polyethylene, a blend of polyethylenes or ethylene copolymers; a core, comprising one or more than one layer, made from a blend of polypropylene, linear low density polyethylene, a polymer compatibilizer or tie-layer resin, and/or low density polyethylene, said core being applied against the inner layer; and an outer layer (same or different from the inner layer or the core layer) is made of a polyethylene or a blend of polyethylenes with or without ethylene copolymers, said outer layer being applied against the core and opposite the inner layer; said multi-layer film having an overall thickness of lower or equal to 2.5 mil and at least one of the properties listed hereinafter: a stiffness (as measured by 1% secant modulus in the film direction) varying from 79000 psi to 140000 psi; a tensile strength at yield of from 2100 psi to 3300 psi; (measured in film machine direction) and a tensile strength at break of from 4700 to 6700 psi (measured in film machine direction). A method of forming, sealing and filling a pouch with said film, a pouch formed with said film and use of said film to form a pouch.

### FIELD OF THE INVENTION

The invention relates to an improved thin film for vertical form, fill and seal (VFFS) systems for packaging any kind of flowable materials (preferably liquids such as milk).

### DESCRIPTION OF THE PRIOR ART

Film for vertical form, fill and seal (VFFS) systems for liquid packaging must travel well through a vertical form, fill and seal machine (i.e. have good machinability) and have the ability to be easily sealed. In addition, film for milk pouches are required to be sufficiently stiff so that they can stand upright in a jug. This facilitates the pouring of the milk from the plastic pouch. There are significant advantages of being able to prepare thin films which may be used in high speed form, fill and seal (FFS) systems. One of these advantages is the increased number of pouches—i.e. the yield—from each pound of film. However, the stiffness of the film should not be compromised during the “down-gauging” of the material. Indeed it has to be enhanced to ensure that the pouch can remain standing in the jug.

Recently it has been described in U.S. Pat. No. 6,237,308B1 (Quintin et al.)assigned to Glopak Inc., a multi-layer film structure with polyethylene sealant layers and a core made up of a blend polypropylene (PP) and low density polyethylene (LDPE) to improve the strength of the heat sealed pouches prepared by VFFS machines. The core may also contain linear low density polyethylene (LLDPE) in the blend of LDPE and PP.

Theoretically, this film structure reduces the thinning of the plastic in the area of the seal because at the pressure and temperature used during the sealing of the pouch, the polypropylene (PP) is less fluid and mobile compared to the sealant layer polymer blend. There is a tendency for the film at the seal to stretch and thin out because of the combined effect of the temperature, pressure between the sealing jaws, and weight of the contents of the pouch pulling on the film during sealing.

The maximum VFFS filling speed attainable with the use of this film is limited unless the amount of polypropylene (PP) in the core is low. At high levels of polypropylene the quality of the seals suffer because of incompatibility between the polypropylene and the low density polyethylene (LDPE) in the core. This incompatibility causes the precipitation of grains of polypropylene (PP) or polypropylene (PP) together with polyethylene (PE) in separate phases and results in the creation of hard inclusions in the area of the seal. The problem is exacerbated at higher levels of polypropylene (PP). Also, if the sealed pouches are kept in the cold, as would be expected for a refrigerated product, the number and size of the hard inclusions/nodules may increase.

### SUMMARY OF THE INVENTION

The present invention relates to a technical advance to the art which allow the creation of a multi-layer film without the problems of the inclusion of nodules in the seal area even if the proportion of PP in the film core is high. A purely illustrative and non limiting example of a high PP proportion may be upwards of 40% w/w) in the core of a multilayer film. This film also seals more rapidly because it shows enhanced heat transfer characteristics.

The Applicant has noted that the higher is the proportion of PP in the film, higher is the required temperature of the sealing jaws. Also, the Applicant has noted that if a polymer compatibilizer (such as for example EMAC (ethylene methacrylate copolymer) or any other polymer compatibilizers) is present in the blend of polymers used in the core, when the amount of PP increases, the relative increase of the required sealing temperature to obtain the same quality seal is less (when compared to a film having no polymer compatibilizer of the low melting multi-functional variety).

Apparently, without being formally bound to the following interpretation, this may be owed to the fact that the coefficient of thermal conductivity of PP is lower than that for LLDPE. Therefore the higher is the proportion of PP in the core, lower is the rate of heat transfer across the film during sealing. However, if a polymer compatibilizer (e.g. EMAC or other polymer compatibilizers) is introduced in the core, the melt temperature of the core is lowered. The Applicant has noted that when the core is partially molten during sealing, a more rapid transfer of heat across the film is obtained.

More particularly, according to a first preferred embodiment, the present invention relates to a multi-layer film for vertical form, fill and seal systems for liquid, powder, granules and/or other flowables packaging, said multi-layer comprising:
an inner layer made of polyethylene, or a blend of one or several polyethylenes and/or one or several ethylene copolymers (preferably a blend of one or several polyethylenes with or without one or several ethylene copolymers);
a core, comprising one or more than one layer, made from a blend of:
   polypropylene;
   linear low density polyethylene;
   a polymer compatibilizer or tie-layer resin; and/or
   optionally low density polyethylene;
said core being applied against the inner layer; and
an outer layer (same or different from the inner layer or the core layer) made of a polyethylene or a blend of polyethylenes with or without ethylene copolymers, said outer layer being applied against the core and opposite the inner layer;
   said multi-layer film having an overall thickness lower or equal to 2.5 mil, preferably an overall thickness varying from 1.75 mil to 2.5 mil. More particularly said multi-layer film may further have at least one of the properties listed hereinafter:
a stiffness (as measured by 1% secant modulus (ASTM D 882) in film machine direction) varying from 79,000 psi to 140,000 psi ;
a tensile strength at yield of from 2100 to 3300 psi (ASTM D882), measured in film machine direction); and
a tensile strength at break of from 4700 psi to 6700 psi (measured in film machine direction).

The aforesaid multilayer film may optionally further comprise of at least one additional layer adjacent the inner layer or the outer layer. Additional layer(s) may be identical or different from the ones previously described for the inner and outer layers and the core layers. Optionally a polymer compatibilizer may be used, said polymer compatibilizer being as previously mentioned for the above mentioned core layer. Preferably, said additional layer(s) are within the definitions already given hereinbefore for the inner and outer layers and for the core. Also, the eventual polymer compatibilizer is preferably within the definition of those defined herein below as polymer compatibilizers.

Depending on the required film strength and thickness or the rapidness of sealing required the relative thickness of the film layers (outer:core: inner) may vary within large limits. Preferably, aforesaid ratio of the relative thickness of the film layers can be from 10:80:10 to 30:40:30. Films with thicker skins have the ability to seal more quickly, while films with a relatively thick core and with a high proportion of PP in the core are stronger. It is more preferably convenient to have the following relative proportions of outer skin layer to core layer to inner skin layer (25:50:25).

It is to be noted that a measure made according to 1 or 2 percent secant modulus is well known to skilled workmen as a standard engineering measure concerning physical properties characterization of a film. In this regard, a man skilled in the art may refer to ASTM D882. Also, a man skilled in the art should not require any further clarification. Such information is normally included the technical data sheets supplied by resin manufacturers for their film resins. It is similar to the Young's modulus except it recognizes the fact that the initial portion of the stress vs strain curve for plastic materials is not linear and so it does the measurement at a one (1) or two (2) percent offset.

Furthermore, according to a second preferred embodiment, the invention relates to a method of forming, sealing and filling a pouch with a liquid, powder, granules and/or other flowables at high speed on a vertical form, fill and seal system, said method comprising the steps of:
i) providing, in roll form, a multi-layer film as defined hereinabove,
ii) drawing said film, by drawing means, over a pouch former to form a plastic film tube having an overlapped vertical film edge,
iii) sealing said overlapped vertical edge with a vertical sealer to form a vertical seal,
iv) effecting a horizontal seal across said plastic film tube with a horizontal sealing jaw and at a predetermined location below said vertical sealer, and simultaneously severing said tube to form a top horizontal seal for a filled pouch and a bottom horizontal seal for a pouch being filled, said horizontal and vertical seals, and
v) continuously feeding a liquid, powder, granules and/or other flowables within said plastic film tube below said vertical sealing jaw and above said transverse sealing jaw,
   the resulting pouch having walls provided with a thickness lower or equal to 2.5 mil, preferably varying from 1.75 mil to 2.5 mil. More preferably, said thickness may vary from 2.0 to 2.25 mil.

Furthermore, according to a third preferred embodiment, the invention relates to a pouch obtained from a multi-layer film as defined hereinabove and by processing on a vertical, forming, sealing and filling system, said pouch having walls provided with a thickness corresponding to the thickness of said film which is lower or equal to 2.5 mil, preferably said thickness varying from 1.75 to 2.5 mil.

Furthermore, according to a fourth preferred embodiment, the invention relates to a use of a multi-layers film as defined hereinabove for preparing a pouch having walls provided with a thickness corresponding to the thickness of said film which is lower or equal to 2.5 mil, preferably said thickness varying from 1.75 to 2.5 mil on a high speed vertical form, film and seal systems. Preferably, said wall may have a thickness varying from 1.75 to 2.5 mil, especially for the packaging of 0.8 to 1.7 kg of liquid, powder, granules and/or other flowables.

Advantageously, according to a fifth particularly preferred embodiment of the invention, the multi-layer film according to the invention may be prepared by any appropriate process well known to skilled workman.

Advantageously, it is to be noted that thinner films (i.e. thickness<1.75 mil) maybe used to package smaller quantities of liquids, powder, granules and/or other flowables. According to a more particularly preferred aspect of the invention, said multi-layer film may further have at least a stiffness (as measured by 1% secant modulus in film machine direction) varying from 79000 psi to 140000 psi.

Preferably, as the film thickness is reduced it may be advantageous to modify the composition of the film core by for example increasing the percentage of polypropylene such that the film stiffness is increased. By way of illustrative and non limiting examples, we may then conveniently vary film stiffness with thickness such that:
1. A film with a thickness of 2.5 mil has a stiffness of at least 480 MPa (69,618 psi);
2. A film with a thickness of 2.25 mil has a stiffness of at least 658 MPa (95498 psi);
A film with a thickness of 2.00 mil has a stiffness of at least 938 MPa (135973 psi).
   The aforesaid variation in film stiffness as a function of thickness is offered as an illustrative and non limiting example of how one may “downgauge” and still have a film that is stiff enough to be used to package a fluid (such as for example milk) in a VFFS pouch. According to this particularly preferred application, the stiffness and thickness of the multi-layer film is such that the pouch obtained could remain upright in the jug/container.

Alternatively, it may be preferable and possible to chose to make the thicker film be stiffer than required for the particular application.

More particularly, the present invention relates to the fact that low density polyethylene limits the performance of the film, and that a much superior structure is created by lowering and preferably eliminating the LDPE in the core of multi-layer structures which contain polypropylene (PP). The superior structure is created because LDPE is not particularly compatible with PP. The lack of compatibility contra-indicates the use of high levels of PP in the core of the film. However high levels of PP are desirable for the creation of a stiffer and stronger film.

The use of the compatibilizer reduces the tendency of the linear low density polyethylene (LLDPE) and the polypropylene (PP) to form separate phases and prevent the formation of hard nodules of polymers (or polymer blends) in the seal area of the film when high levels of polypropylene (PP) are used. This also facilitates faster film sealing since at a lower temperature the compatibilizer promotes the melting of the film layers. Also, this melting, whether in whole or in part, further contributes to promote the transfer of heat from the sealing element through the film to the sealant layer on the inside wall of the pouch. A rapid transfer of heat through the pouch wall facilitates the melting of the sealant surfaces such that the necessary interpenetration of polymer chains which is required to have good seals occurs.

If high levels of polypropylene (PP) are present in the core of the multi-layer film and there is no compatibilizer, such as for example the lower melt temperature ethylene methacrylate copolymer (EMAC)—the rate of heat transfer across the film structure tends to go down relative to that which would occur if the film had a polyethylene (PE) core. This is one consequence of the fact that the coefficient of thermal conductivity of polypropylene (PP) is less than that of polyethylene under the conditions typically used during the sealing of polyolefin or related film structures in VFFS equipment. In addition to the increased rates of heat transfer and therefore the possibility of more rapid sealing; the film structure has better integrity because the compatibilizer helps to “weld” the multiple layers of film together, i.e. the tendency for film layer de-lamination is less.

Another preferred aspect of the invention relates to the fact that the use of the compatibilizer such as EMAC (ethylene methacrylate copolymer) make the film blend more supple and pliable. This increased suppleness is due to the fact that the functional group on the compatibilizer is more bulky than the usual ethylene or propylene group. Thus introduction of this polymer into the resin blends causes the crystallized polymer in the film to be more open, and indeed, somewhat less crystalline. The net result is—all things being equal—a film that is more supple when certain compatibilizers such as for example EMAC, is/are incorporated in the film. This contributes to improved film machinability; since it allows it to pass over structures, such as the tube former or more specifically the “forming shoulders” in the VFFS machine without becoming permanently creased. Films with high levels of PP in PP-LLDPE or PP-LDPE blends tend to crease and “stress-whiten” when folded. The tendency for this permanent defect to occur in folded film is markedly less when a compatibilizer such as EMAC is included in the resin blend. Its incorporation “softens” the film without compromising unduly the strength and stiffness of the film.

Another preferred embodiment of the invention relates to the introduction of a clarifier either by the use of pre-clarified PP grade, or by separate addition, to create a clear film even when high levels of PP are present in the blend. A clearer film is desirable for the packaging of milk, liquids, and/or other flowables. The clearer film offers the consumer and packager an opportunity to assess product quality by eye. The clarifier improves the aesthetic appeal of the film without compromising the physical properties of the film. The mechanism of clarification requires that the PP layer is nucleated to such an extent that many small PP spherulites are produced upon cooling as opposed to fewer spherulites than can grow to create larger particles of PP or PP-PE blends.

An additional benefit of the greater degree of nucleation in the presence of the clarifier is that it contributes to the reduction in the formation of hard nodules at the area of the film seal during VFFS operation. Typically these hard nodules grow when the film cools in the area of the seal. They can continue to grow during the storage of the sealed milk pouches. If the amount of compatibilizer used is sufficient, then it is not necessary to add a clarifier for the purpose of eliminating the creation of nodules in the area of the film seal. So optionally—as a non-limiting example—one may choose to increase the amount of EMAC in the core to 8% (w/w percent) and not include a clarifying agent if the core has 70% w/w of polypropylene and 20% w/w of LLDPE.

A skilled workman knows the suitable polypropylene (PP) clarifiers and/or nucleating agents which may be used. Preferably, such clarifier may be selected from the group consisting of 4-biphenyl carboxylic acid, thymine, talc, sodium benzoate or dibenzylidene sorbitol_(DBS); bis (p-methyl-dibenzylidene sorbitol) (MDBS) and related sorbitol derivatives. The amount of clarifier that may be preferably typically used may represent from 0.05 to 0.5% w/w of the total composition of the multi-layer film.

Particularly preferred multi-layer film structures according to the invention have been developed with a high proportion of polypropylene blended with linear low density polyethylene and a polymer compatibilizer in the core. These new film structures can be used at high speed in VFFS systems because there is no precipitation of polyethylene (PE), polypropylene (PP) or PP-PE blends that are incompatible with the bulk polymer solid solution at the sealing zone. The presence of such precipitated material in the area of the seal compromises seal quality. The new film structures provide significant improvements over traditional film structures even when the gauge of the new structure is less because the higher proportion of polypropylene in the core enhances the strength and stiffness of the film.

This development leads to a significant improvements to the art because it allows:
i) The down-gauging of film for the VFFS packaging of milk and other liquids and/or flowable material, with the concomitant improvements in film yield and reduction in scrap;
ii) Faster film sealing without the creation of nodules or inclusions of material of a different phase or crystalline structure in the sealing zone;
iii) The incorporation of a polymer with a higher melt temperature, stiffness and strength in the film core; and
iv) The creation of a film for VFFS with a significant amount of a stiff polymer such as PP which is nevertheless supple and pliable enough to not become creased when folded or pulled across forming shoulders—of the tube former—and other structures in the VFFS machine.

These improvements to the art are of great benefit to the VFFS milk, liquid and/or other flowables packaging industry.

### BRIEF DESCRIPTION OF THE DRAWINGS

Particularly preferred embodiments of the invention will be described hereinafter with reference to the following drawings:

FIG. 1 is a schematic diagram illustrating basic component parts of high-speed pouch forming, sealing and filling machine;

FIG. 2 is a schematic view of a process for the preparation of a multilayer film;

FIG. 3 is a graphic expression of film strength at yield for typical films manufactured in the manner of the invention;

FIG. 4 is a graphic expression of the film stiffness for typical films manufactured in the manner of the invention; and

FIG. 5 is a graphic expression of the break strength as a function of the percentage of polypropylene (PP) in the core layer of the film.

### DETAILED DESCRIPTION OF PARTICULARLY PREFERRED EMBODIMENTS

According to a first particularly preferred embodiment, the invention relates to a multi-layer film for vertical form, fill and seal systems for liquid, powder, granules and/or other flowables packaging, said multi-layer comprising:
an inner layer made of polyethylene, or a blend of one or several polyethylenes and/or one or several ethylene copolymers (preferably a blend of one or several polyethylenes with or without one or several ethylene copolymers);
a core, comprising one or more than one layers, made from a blend of:
   polypropylene;
   linear low density polyethylene;
   a polymer compatibilizer or tie-layer resin; and/or
   optionally low density polyethylene;
said core being applied against the inner layer; and
an outer layer (same or different from the inner layer or the core layer) made of a polyethylene or a blend of one or several polyethylenes and/or one or several ethylene copolymers (preferably a blend of one or several polyethylenes with or without one or several ethylene copolymers), said outer layer being applied against the core and opposite the inner layer;
   said multi-layer film having an overall thickness lower or equal to 2.5 mil, preferably an overall thickness varying from 1.75 to 2.5 mil, and at least one of the properties listed hereinafter (for a typical multi-layer film with outer layer:core-layer:inner layer with relative proportions of 25:50:25):
a stiffness (as measured by 1% secant modulus in the film direction ) varying from 79000 psi to 140000 psi;
a tensile strength at yield of from 2100 psi to 3300 psi (measured in film machine direction); and
a tensile strength at break of from 4700 psi to 6700 psi (as measured in the film's machine direction), preferably 5000 to 6500 psi (machine direction).

Preferably, the polypropylene may be a random copolymer polypropylene or blend of homo-polymer polypropylenes and/or copolymer polypropylene. To prepare a high impact strength version of the film the grade of polypropylene or blend of polypropylene(s) used will be such that the izod impact strength of the PP is greater than 9 ft.lb_{f} per inch of notch as per American Society for Testing and Materials (ASTM) standard D256. More preferably, a particularly suitable polypropylene may be a high impact copolymer blown film grade with an izod impact strength (ASTM D257, at 23° C.) of from 8 to 80 lb/f per inch of notch., and melt flow index (ASTM D1238, 2.16 kg, 230° C.) of from 0.3 to 5.5 g/10 min

Preferably, the linear low density polyethylene (LLDPE) for the core layer preferably may have a melt index (ASTM D1238, 2.16 kg, 190° C.) from 0.4 to 2.00 g per 10 minutes and a density of approximately 0.926 g/cc. An LLDPE with a higher melt index maybe used provided the temperature at which the film is extruded is sufficiently low to ensure that the film has the correct melt strength to allow successful blowing—and/or casting—into film. A man skilled in the art may choose to use an LLDPE of a higher or lower density, as a means of modifying the final puncture resistance or tensile strength of the film. More preferably, a particularly suitable polyethylene may be a linear low density polyethylene (LLDPE) with a melt index from 0.3 to 1.0.

Preferably, the polymer compatibilizer may be selected from the group consisting of ethylene methacrylate, ethylene methacrylate copolymer, ethylene butyl acrylate, ethylene vinyl acetate, ethylene propylene diamine rubber, ethylene propylene copolymer, ethylene styrene copolymer, and ethylene thermoplastic elastomers. As one skilled in the art would realize, the higher the proportion of copolymer content in an ethylene-copolymer type compatibilizer, the lower the amount of ethylene-copolymer type compatibilizer would be required. Thus by way of illustrative and non limiting example, one may use 8% of a 20% methacrylate content EMAC or 7% of 24% methacrylate content EMAC and achieve similar degrees of compatibilization of the polymer blend in the core of the film. More preferably, said compatibilizer may be such as, but not limited to one of ethylene methacrylate (EMA), ethylene methacrylate copolymer (EMAC), ethylene butyl acrylate, ethylene vinyl acetate (VA), ethylene propylene diamine rubber (EDPM), Versify® (ethylene propylene copolymer); ethylene styrene copolymer (Index® copolymers), Engage®, Lotryl® and/or the tie-layer polymers between PP and PE. A 20% methacrylate content ethylene methacrylate copolymer (EMAC) is particularly convenient for use in this application. A particularly preferred compatibilizer is ethylene methacrylate copolymer with 20% or more of methacrylate content. (Advantageously, when the polymer compatibilizer comprises ethylene methacrylate copolymer (EMAC), it may have from 10 to 25% of methacrylate content.)

Material that works as compatibilizers often also works as tie-layer resins. Any tie-layer polymer well known to skilled workmen as appropriate to bind PP with PE may be used. Preferably, said tie-layer polymers may be selected from the group consisting of ethylene methacrylate (EMA), ethylene methacrylate copolymer (EMAC), ethylene butyl acrylate, ethylene vinyl acetate (VA), ethylene propylene diamine rubber (EDPM), Versify® (ethylene propylene copolymer); ethylene styrene copolymer (Index® copolymers), Engage®, Lotryl® other functional copolymers or ter-polymers, other ethylene propylene copolymers; anhydride or maleic anhydride modified linear low density polyethylene, modified ethylene acrylate carbon monoxide ter-polymers, and ethylene ethyl acrylate copolymer (EEA). A particularly preferred tie-layer resin is ethylene methacrylate copolymer with 20% or more of methacrylate content.

Preferably, the low density polyethylene may have a density varying from 0.918 0.925 and melt index varying from 0.20 to 1.0 g/10 min.

A particularly preferred polymer blend for the inner layer may be comprised of from 70 to 100% of an Ultra Low Density Ethylene/Octene Copolymer (ULLDPE)—density 0.905 g/cc to 0.913 g/cc, ASTM D1238 (2.16 kg, 190° C.—melt index of 0.5 to 1.2 g/10 min) or a metallocene catalysed hexene very low density polyethylene (mVLDPE, density 0.905, to 0.13 g/cc with melt index of 0.5 to 1.2 g/10 min (ASTM D1238, 2.16 kg, 190° C.). Advantageously, this lower density polyethylene may be profitably blended with a fractional melt low density polyethylene to improve the melt strength and assure better bubble stability during blown film extrusion. However if the appropriate extrusion conditions are chosen it is not necessary to add the low density polyethylene to the formulation. The Applicant has noted that the use of the lower density ULDPE or mVLLDPE causes the inner skin to have a relatively low seal initiation temperature. The Applicant has also noted that a lower seal initiation temperature promotes greater speed in the vertical form fill and seal (VFFS) operation, since the rate limiting step is often the rate at which pouches can be made and sealed.

Preferably, without being bound to the following process of preparation, said multi-layer film may be prepared according to a process comprising a multilayer blown film processing extruder such that two skin layers and a core with at least one layer is prepared. The skin layers may be prepared with a blend of linear low density polyethylenes with a density such that the seal initiation temperature is sufficiently low to achieve rapid sealing during VFFS operation. The LLDPE may preferably have densities from 0.915 g/cc to 0.89 g/cc. The core may be a single layer of a polypropylene blended with a polypropylene polyethylene compatibiliser. A suitable compatibiliser may be preferably ethylene methacrylate copolymer (EMAC) with a methacrylate content of 20%, or one or another (or combination there of) from the list of compatibilisers and/or tie-layer resins provided above. The core may also be a single layer of polypropylene (PP) blended with linear low density polyethylene (LLDPE) and a compatibiliser such as ethylene methacrylate copolymer (EMAC) or one or another polymer selected from the list of compatibilisers discussed above. Preferably the film may be prepared with a blow up ratio (B.U.R) of at least 2. A multilayer core may also be produced, of layers of polypropylene or polypropylene-polyethylene blends with a suitable compatibiliser or tie-layer polymer such as EMAC or other material detailed herein.

Preferably, said multi-layer film may be used for the vertical form and seal packaging of 200 grams or more of liquid, powder, granules and/or other flowables. More preferably, a liquid is packaged such as a non limiting-example milk.

More particularly, the fluid packaging is liquid, (or powder, granules and/or other flowables) packaging and the blend defining the core layer comprises in weight percent:
10% to 90% of polypropylene or a mixture of polypropylenes;
80% to 0% (preferably the lower limit of 0% is excluded from the range) of a linear low density polyethylene (LLDPE) or a mixture of linear low density polyethylenes (LLDPEs) and low density polyethylene (LDPE); and
2% to 10% of at least one polymer compatibilizer.

Advantageously, an appropriate amount of clarifier may be optionally further added. Preferably, such a clarifier may be of any kind well known to skilled workmen. More preferably, said clarifier may be based on sorbitol, modified sorbitol chemistry, or other nucleating agent suitable for the promotion of the crystallization of PP, maybe added to ensure that the optical density of the resulting film is less than 0.7%, if a clear film is required. However other optical density can be selected within the field of the invention, and for many applications where only good contact clarity or else the film will be colored and/or pigmented or printed it may or may not be necessary to include a clarifying agent or use a preclarified grade of polypropylene.

According to a second preferred embodiment, the invention relates to a method of forming, sealing and filling a pouch with a liquid, powder, granules and/or other flowables at high speed, said method comprising the steps of:
i) providing, in roll form, a multi-layer film as defined hereinbefore,
ii) drawing said film, by drawing means, over a pouch former to form a plastic film tube having an overlapped vertical film edge,
iii) sealing said overlapped vertical edge with a vertical sealer to form a vertical seal,
iv) effecting a horizontal seal across said plastic film tube with a horizontal sealing jaw and at a predetermined location below said vertical sealer, and simultaneously severing said tube to form a top horizontal seal for a filled pouch and a bottom horizontal seal for a pouch being filled, said horizontal and vertical seals, and
v) continuously feeding a consumable liquid, powder, granules and/or other flowables within said plastic film tube below said vertical sealing jaw and above said transverse sealing jaw.

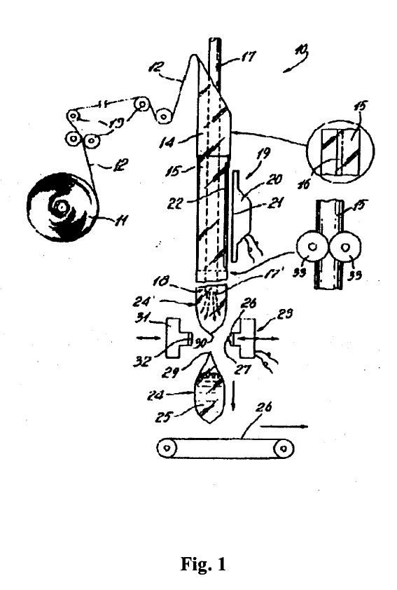

Advantageously, said method is processed on a high speed vertical form, fill and seal system as shown in FIG. 1.

Blown film coextrusion is a highly versatile technology covering a wide range of applications including complex structures based on 2 or more (preferably 2 to 9) layers—but not limited to 9 at the upper limit to the number of layers—of the same or different materials.

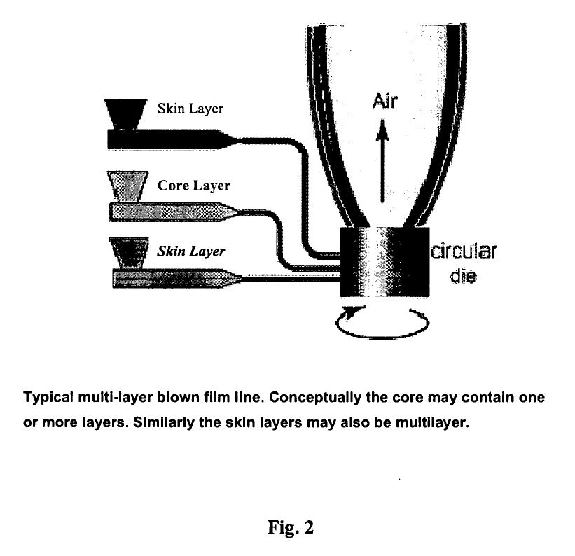

As shown in FIG. 2, melted polymer is extruded through a circular die and the tube is filled with air to blow it. Many parameters are adjustable to achieve the right properties. Technique of blown film co-extrusion are well known to skilled workmen and do not need to be described in detailed. This process may be summarized as follows: A multilayer blown film processing extrusion line such that two skin layers and a core with at least one layer is prepared. The skin layers will be prepared with a blend of linear low density polyethylenes with a density such that the seal initiation temperature is sufficiently low to achieve rapid sealing during vertical form fill and seal operation. The typical LLDPE may preferably have densities from 0.915 g/cc to 0.89 g/cc. The core maybe a single layer of a random copolymer polypropylene blended with a polypropylene-polyethylene compatibiliser. A suitable compatibiliser being ethylene methacrylate copolymer (EMAC) with a methacrylate content of 20%, or one or another (or combination there of) from the list of compatibilisers and/or tie-layer resins provided herein. The core may also be a single layer of polypropylene (PP) blended with linear low density polyethylene (LLDPE) and a compatibiliser such as ethylene methacrylate copolymer (EMAC) or one or another polymer selected from the list of compatibilisers provided herein. Preferably the film will be prepared with a blow up ratio (B.U.R) of at least 2. A multilayer core may also be produced, of layers of polypropylene or polypropylene-polethylene blends with a suitable compatibiliser or tie-layer polymer such as EMAC or other material detailed in the list of tie-layers or compatibilizers above.

Optionally, the outer layer, the core and/or the inner layer may further comprise one or several additives useful to make easier the processing of a film in a vertical form, fill and seal system, such as for example polymer processing aids concentrate and/or slip/antiblock concentrates. Any of such additives well known to skilled workman can be used. Advantageously, the following additives are particularly preferred:

Slip Agent:

200 to 2000 ppm of a “slip” agent well known to skilled workman. A preferred slip agent is erucamide or other fatty acide amide such as oleamide. The slip agent lowers the coefficient friction of the film and allows it to slide readily over various surfaces;

Blocking Agent:

1000 to 5000 ppm of any film anti-blocking agent well known to skilled workman maybe added to the film layers. Preferably from 1000 to 5000 ppm of an anti-blocking material such as diatomaceous earth, synthetic silica or talc will be added to the inner and outer layers of the film. The anti-blocking material is particularly useful in reducing the coefficient of friction between the film and the metallic surfaces over which the film is drawn during the VFFS process.

Processing Aid:

50 to 1000 ppm of any processing aid well known to skilled workman, preferably and not limitatively a 50 ppm to 1000 ppm of a fluoro-elastomer based polymer processing aid maybe added to outer and inner skin layers of the film.

In the following particularly preferred example, the formulation of each layer is as described hereinafter.

Preferably, said multi-layer may comprise:

an inner layer made from the mixture of :
79.10% of ATTANE 4201 (ultra low density ethylene/octane copolymer; density: 0.912 g/cm3;);
18.50% of DOW Polyethylene 133A (low density polyethylene; density: 0.923 g/cm3);
1.85% of a concentrate of 50,000 ppm erucamide as slip agent and 100000 ppm of diatomaceous earth or other suitable film anti-blocking agent; density: 0.980 g/cm3);
0.55% of a 3% fluoro-elastomer based polymer processing aid (PPA) concentrate to reduce the tendency of the metallocene-LLDPE (m-LLDPE) layer or ultra-low LLDPE (u-LLDPE) to have melt fracture or sharkskin;_{—}
a core layer made from the mixture of:
   from 62 to 68.85% or more of polypropylene (PP) such as for example one or combination of DOW PP D114.01 (ρ=0.903 g/cc, melt flow rate 0.42 g/10 min (ASTM 1238) or Sunoco PP TI 4007G (ρ=0.9 g/cc, melt flow rate 0.7 g/10 min (ASTM 1238) or Total Petrochemicals PP 4170 (ρ=0.905 g/cc, melt flow rate 0.75 g/10 min (ASTM 1238));
   27.6% to 20.85% of NOVA FP026-F (linear low density polyethylene; density: 0.926 g/cm3) or similar LLDPE;
   8.00% of EMAC SP 2207 (20% methacrylate content, ρ=0.941 g/cc, melt index 6.00 g/10 min (ASTM D1238, 2.16 kg, 190° C.) as compatibilizer);
   1.15% of a 5% erucamide or other suitable slip concentrate. The required amount of slip is such that the coefficient of friction of the film after equilibration of the slip in the film is such that the film moves smoothly through the VFFS filler;
   1.150% of a 10% polypropylene clarifier/nucleating-agent concentrate. A suitable nucleating agent is Bis (p-methyl benzylidene sorbitol). The clarifier may not be necessary for those applications where the goal is merely to have good contact clarity.
   an outer layer made from the mixture of:
79.10% of EXXON MOBIL EXCEED 1012CA (mVLDPE resin; density: 0.912 g/cm3);
18.50% of DOW Polyethylene 133A (low density polyethylene; density: 0.923 g/cm3);
1.85% of a concentrate of “50,000 ppm erucamide as slip agent and 100000 ppm of diatomaceous earth or other suitable film anti-blocking agent
0.55% of a 3% fluoro-elastomer based polymer processing aid (PPA) concentrate to reduce the tendency of the metallocene-LLDPE (m-LLDPE) layer or ultra-low LLDPE (u-LLDPE) to have melt fracture or sharkskin.

More particularly, with reference to FIG. 1, there is shown generally at 10 basic component parts of a high-speed pouch forming, filling and sealing machine constructed in accordance with the present invention. These basic component parts are only schematically illustrated and are well known in the art. The improvement in the machine resides primarily in the vertical sealer operating characteristics and the horizontal sealing jaws characteristics, as will be described later. The sealers are controlled to operate with a new multi-layer film whereby to increase the throughput of the machine and provide filled pouches having improved strength and wherein the seals are greatly improved over those of the prior art, thereby resulting in a machine which can output more filled pouches, achieve a significant waste reduction and less downtime as compared with prior art machines using a 76 microns (3 mil) mono-layer polyethylene film. As herein shown the high-speed pouch forming, sealing and filling machine comprises a film roll 11 provided with a multi-layer film 12 which is guided through guide rolls and tensor rolls 13 to a top end of a pouch former 14 where the plastic film is guided and folded to form a plastic film tube 15 having an overlap vertical film edge 16. A filler tube 17 extends within the pouch former 14 and the tube 15 and has a liquid discharge end 17′ positioned at a filling location 18.

A vertical sealer 19 has a sealing head 20 provided with a heating element 21 and a backing member 22 is disposed vertically aligned behind the overlap vertical film edge 16. A vertical seal is formed by fusing the overlapped edge 16 along the plastic tube 15 above the filling location 18. A horizontal sealing jaw assembly 23 is provided spaced at a predetermined distance below the filling location 18 whereby to form a horizontal seal across the film tube 18 and at the same time sever the tube to form a sealed pouch 24 filled with a consumable liquid 25 therein. The pouch is then released on a discharge conveyor 26.

The horizontal sealing jaw assembly 23 is comprised of a sealing head 27 provided with an electrical impulse sealing wire element 28 to sever the film tube as well as to form a top horizontal seal 29 for the pouch 24 and a bottom horizontal seal 30 for the next pouch being formed herein illustrated by reference numeral 24′. The horizontal sealing jaw assembly 23 also has a backing member 31 which is provided as a rubber or Teflon® pad 32 to serve as a backing for the electrical impulse sealing wire element 27. From time-to-time it is necessary to change the pad and the wire element as they wear down. By operating at lower temperature, 10° C.-15° C. lower than the prior art discussed above, these elements have a longer life cycle and there is less machine stoppages. The jaw assembly 23 may move in and out in unison to form the seal or the backing member 31 may be stationary and positioned close to the film with only the sealing head 26 moving in and out. Other suitable sealing assemblies are conceivable provided they can achieve the same results. The film sheet 12 is drawn in continuous motion by a pair of draw rolls 33 in a manner well known to the art. So far we have described the basic component parts of a well known pouch forming, sealing and filling machine such as the Thimonnier M3200®, Thimonnier M5200® or a Prepak IS-7®.

The present invention resides in the provision of a novel multi-layer film structure in combination with the machine to enhance the performance of the machine. This enhancement is achieved by controlling the temperature of the sealing assemblies 19 and 23 wherein they operate at temperatures that are lower than prior art machines. The draw rolls 33 are also operated at higher speeds whereby to increase the throughput of the machine while producing horizontal seals which are much superior than the above-mentioned prior art machines and resulting in a production having less post consumer waste and permitting the machine to operate with less downtime previously caused by malfunction or plastic film roll change.

Typical Comparative Data

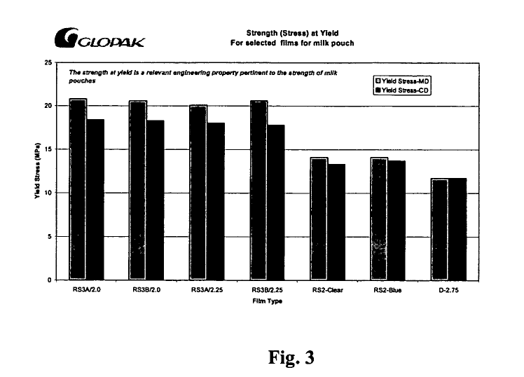

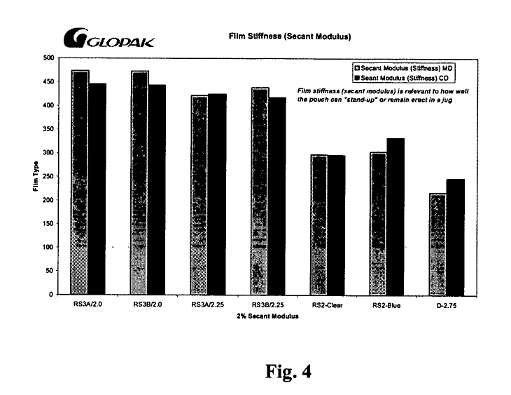

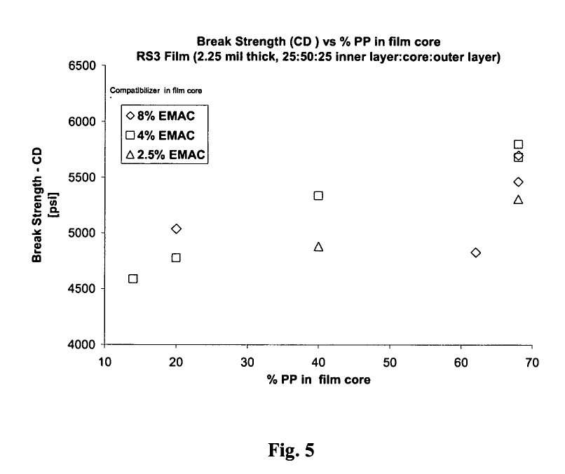

Table 1 with reference to the enclosed FIGS. 3, 4, and 5, shows a typical formulation which show respectively tensile, secant modulus (stiffness) and break strength data, highlights the improvement in physical properties that are possible when high levels of PP are used in conjunction with the compatibilizer EMAC. The films coded RS3 contain EMAC. The numbers in the code represent the film thickness i.e. 2.0 or 2.25 mil. The EMAC changes the crystal structure of the PP-LLDPE blend used in the core to such an extent that this layer has:
i) A strength and stiffness like PP;
ii) The ability to be blown into film more easily than the high melt temperature component (PP);

iii) Sufficient compatibility with the other layers so no delamination occurs. Delamination of film layers will compromise the film strength and performance.

TABLE 1
Typical 2.25 mil thick milk pouch film formulation
(RS3) for increased/improved physical properties and
good seal integrity in high speed VFFS machines

| Exterior of Bags/ | | | | Bag Interior/ | |
|---|---|---|---|---|---|
| Interior of Bubble | | Middle layer | | Exterior of Bubble | |
| Material | (%) | Material | (%) | Material | (%) |
| ULLDPE | 75.60 | LLDPE | 25.85 | m-LLDPE/ | 75.60 |
| | | | | v-LLDPE | |
| LDPE | 22.50 | EMAC | 4.00 | LDPE | 22.50 |
| Polymer | 0.5 | PP | 68.85 | PPA | 0.5 |
| processing | | D114.00 | | | |
| aid | | | | | |
| Concentrate | | | | | |
| Slip/anti- | 1.9 | Slip | 1.30 | Slip/anti- | 1.9 |
| block | | | | block | |
| (5%/10%) | | | | (5%/10%) | |
| concentrate | | | | concentrate | |

N.B. for the data shown in the accompanying figures the outer and inner layer formulations were held constant while the proportion of EMAC and the relative ratio of PP to LLDPE in the core-layer were varied. The ratio outer layer:core layer:inner layer being 25:50:25.

The film coded as D-2.75 is a commercially available 2.75 mil mono-layer polyethylene film that is often used in VFFS systems for the packaging of milk. The films coded RS2 clear or RS2 blue, are three layer films with a blend of LDPE, LLDPE and PP in the core but no EMAC. The lack of EMAC and/or compatibilizer, the presence of LDPE and the relatively low amounts of PP limits the strength and efficacy of these films relative to the “RS3” films.

Of course, the above description of the embodiments of the invention is not limitative and also comprises all possible variations and embodiments that may seems obvious to a man skilled in the art.

What is claimed is:

1. A multi-layer film for vertical form, fill and seal systems for liquid, powder, granules and/or other flowables packaging, said multi-layer comprising:
an inner layer made of polyethylene, a blend of one or several polyethylenes and/or one or several ethylene copolymers;
a core, comprising one or more than one layer, made from a blend of:
polypropylene;
linear low density polyethylene;
a polymer compatibilizer or tie-layer resin; and/or
optionally low density polyethylene;
said core being applied against the inner layer; and
an outer layer (same or different from the inner layer or the core layer) is made of a polyethylene or a blend of one or several polyethylenes with or without one or several ethylene copolymers, said outer layer being applied against the core and opposite the inner layer;
said multi-layer film having an overall thickness of lower or equal to 2.5 mil.

2. A multi-layer film according to claim 1, wherein said film has an overall thickness of 1.75 to 2.5 mil.

3. A multi-layer film according to claim 1, wherein the relative thickness of the inner layer:core layer:outer layer vary from 10:80:10 to 30:40:30.

4. A multi-layer film according to claim 2, wherein the relative thickness of the inner layer:core layer:outer layer is 25:50:25.

5. A multi-layer film according to claim 3, wherein said film further has at least one of the properties listed hereinafter:
a stiffness (as measured by 1% secant modulus in film machine direction) varying from 79000 psi to 140000 psi; and
a tensile strength at yield of from 2100 psi to 3300 psi (measured in film machine direction); and
a tensile strength at break of from 4700 psi to 6700 psi (measured in film machine direction).

6. A multi-layer film according to claim 5, wherein said film at least has a stiffness (as measured by 1% secant modulus) varying from 79000 psi to 140000 psi.

7. A multi-layer film according to claim 1, wherein the blend defining the core layer comprises in weight percent:
10% to 90% of polypropylene or a mixture of polypropylenes; 80% to 0% (lower limit not comprised) of a linear low density polyethylene or a mixture of linear low density polyethylenes and low density polyethylene; and
2% to 10% of at least one polymer compatibilizer.

8. A multi-layer film according to claim 7, wherein the polymer compatibilizer is selected from the group consisting of ethylene methacrylate, ethylene methacrylate copolymer, ethylene butyl acrylate, ethylene vinyl acetate, ethylene propylene diamine rubber, ethylene propylene copolymer; ethylene styrene copolymer, and/or ethylene thermoplastic elastomers.

9. A multi-layer film according to claim 7, wherein the polypropylene is a random copolymer polypropylene or blend of homo-polymer polypropylene and copolymer polypropylene.

10. A multi-layer film according to claim 9, wherein the polypropylene has a grade of polypropylene or blend of polypropylene allowing to prepare a multi-layer film having a high impact strength, the izod impact strength of the polypropylene being greater than 9 ft.lb_{f} per inch of notch as per American Society for Testing and Materials (ASTM) D256.

11. A multi-layer film according to claim 8, wherein the ethylene methacrylate copolymer has from 10 to 25% of methacrylate content.

12. A multi-layer film according to claim 8, wherein the linear low density polyethylene for the core layer has a melt index (ASTM D1234, 2.16 kg, 190° C.) from 0.4 to 2.00 g per 10 minutes and a density of approximately 0.926 g/cc.

13. A multi-layer film for vertical form, fill and seal systems for liquid, powder, granules and/or other flowables packaging, said multi-layer comprising:
an inner layer made of an octene-LLDPE (or other LLDPE) blended with low density polyethylene;
a single and/or multi-layer core made from a blend in weight percent of:
10% to 90% of polypropylene;
80% to 0% (lower limit not comprised) of a linear low density polyethylene or low density polyethylene and a polymer compatibilizer of from 2.5 to 12%, said core being applied against the inner layer;
an outer skin layer made of an LLDPE, blended with low density polyethylene.
said multi-layer film having an overall thickness varying between 1.75 to 2.5 mil for the packaging of 0.8 to 1.7 kg of liquid, powder, granules and/or other flowables or flowables a stiffness varying from 79000 psi to 140000 psi (measured in film machine direction) as measured by the 1% secant modulus; and a tensile strength at yield of from 2100 psi to 3300 psi (machine direction) and a strength at break of from 4700 to 6700 psi (machine direction).

14. A method of forming, sealing and filling a pouch with a liquid, powder, granules and/or other flowables at high speed, said method comprising the steps of:
i) providing, in roll form, a multi-layer film as defined in claim 1,
ii) drawing said film, by drawing means, over a pouch former to form a plastic film tube having an overlapped vertical film edge,
iii) sealing said overlapped vertical edge with a vertical sealer to form a vertical seal,
iv) effecting a horizontal seal across said plastic film tube with a horizontal sealing jaw and at a predetermined location below said vertical sealer, and simultaneously severing said tube to form a top horizontal seal for a filled pouch and a bottom horizontal seal for a pouch being filled, said horizontal and vertical seals, and
v) continuously feeding a consumable liquid, powder, granules and/or other flowables within said plastic film tube below said vertical sealing jaw and above said transverse sealing jaw.

15. A method of forming, sealing and filling a pouch with a liquid, powder, granules and/or other flowables at high speed, said method comprising the steps of:
i) providing, in roll form, a multi-layer film as defined in claim 11,
ii) drawing said film, by drawing means, over a pouch former to form a plastic film tube having an overlapped vertical film edge,
iii) sealing said overlapped vertical edge with a vertical sealer to form a vertical seal,
iv) effecting a horizontal seal across said plastic film tube with a horizontal sealing jaw and at a predetermined location below said vertical sealer, and simultaneously severing said tube to form a top horizontal seal for a filled pouch and a bottom horizontal seal for a pouch being filled, said horizontal and vertical seals, and
v) continuously feeding a consumable liquid—or powder, granules and/or other flowables—within said plastic film tube below said vertical sealing jaw and above said transverse sealing jaw,
the resulting pouch having walls provided with a thickness varying from 1.75 to 2.5 mil and at least one of the properties listed hereinafter:
a stiffness varying 79000 psi to 140000 psi (as determined by 1% secant modulus in the film's machine direction); and
a tensile strength at yield of from 2100 psi to 3300 psi (machine direction); and
tensile strength at break from 4700 to 6700 psi (machine direction).

16. A method of forming, sealing and filling a pouch with a liquid, powder, granules and/or other flowables at high speed, said method comprising the steps of:
i) providing, in roll form, a multi-layer film as defined in claim 13,
ii) drawing said film, by drawing means, over a pouch former to form a plastic film tube having an overlapped vertical film edge,
iii) sealing said overlapped vertical edge with a vertical sealer to form a vertical seal,
iv) effecting a horizontal seal across said plastic film tube with a horizontal sealing jaw and at a predetermined location below said vertical sealer, and simultaneously severing said tube to form a top horizontal seal for a filled pouch and a bottom horizontal seal for a pouch being filled, said horizontal and vertical seals, and
v) continuously feeding a consumable liquid within said plastic film tube below said vertical sealing jaw and above said transverse sealing jaw,
the resulting pouch having walls provided with a thickness varying from 1.75 to 2.5 mil, a stiffness varying 79000 psi to 140000 psi (as determined by 1% secant modulus), a tensile strength at yield of from 2100 psi to 3300 psi (machine direction) and a tensile strength at break from 4700 to 6700 psi (machine direction).

17. A pouch obtained from a multi-layer film as defined in claim 1 on a forming, sealing and filling system.

18. A pouch obtained from a multi-layer film as defined in claim 13 on a forming, sealing and filling system.

19. Use of a multi-layers film as defined in claim 1 for preparing a pouch by processing on a high speed vertical form, film and seal systems.

20. Use of a multi-layers film as defined in claim 13 for preparing a pouch by processing on a high speed vertical form, film and seal systems.
